(19) United States
(12) Patent Application Publication
(10) Pub. No.: US 2004/0071038 A1
(43) Pub. Date: Apr. 15, 2004

(54) System and method for storing and retrieving medical images and records

(76) Inventor: Janet R. Sterritt, Hollis, NH (US)

Correspondence Address: Cesari and McKenna, 88 Black Falcon Avenue, Boston, MA, 02210, US

(21) Appl. No.: 10/432,735

(22) PCT Filed: Nov. 21, 2001
(86) PCT No.: PCT/US01/43131

(30) Foreign Application Priority Data
Nov. 24, 2000 (US) 60252971

(51) Int. Cl. G11C 8/02

(52) U.S. Cl. 365/232

(57) ABSTRACT

A system and method for recording removable media (such as data CDs) that include information enabling data to be read from a proprietary standard, such as DICOM, on any predetermined computer platform without the need of specific computer hardware or software is provided. A specialist/medical facility computer receives data from a variety of sources/modalities including an image scanner, a network transporting DICOM-format data, document scanners and supporting text data therefor, and forms the data into appropriate files and directories in the DICOM format. These data files are recorded on a removable media, such as a CD, along with various applications and other information that can be executed on a computer that may not include DICOM hardware and software. To this end, the removable media can include a universal viewer application that forms associations with data stored on the media so any interested party with a PC can view the data in the same form as the original modality. In this manner the patient can provide unedited data to a variety of interested parties.

### BACKGROUND OF THE INVENTION

1. Field of the Invention

This invention relates to storage and retrieval of records and images using computer-based data storage and reading devices, and more particularly to the storage and retrieval of records in medical environments.

2. Background Information

By law, a medical facility that creates the medical image is responsible for maintaining the patient's record. Therefore, the facility must house and create a library for its images. The images belong to the medical facility not to the patient If a patient desires to have a second opinion or pursue other advice using these images, the patient must request that duplicates be made. In virtually every medical facility today, there is a demand created by the patient to duplicate film.

With the progressing evolution toward digital images and electronic records, many health care facilities presently store a patient's medical record in digital format. The American College of Radiology has created and adopted the Digital Imaging and Communications in Medicine (DICOM®) 3.0 protocol and format in an effort to standardize the storage and read-back of such records. Reference is made generally to the DICOM support manual, which defines the commercially available system and software product. One current source for the published DICOM standard (year 2000 draft, Parts 1-15) can be found via the well-known Internet at the URL address http://medical.nema.org/dicom/2000.html, which can be accessed alternatively via the American College of Radiology via the Internet at the URL address http://www.acr.org.

Notwithstanding the use of a somewhat portable and universal record storage format, the basic precepts and business model remain the same for the digital record as was formerly used for the analog/physical record—the hospital must physically store and maintain the medical record on site (e.g. in its possession). This is because the law states that such storage is the hospital's responsibility.

Accordingly, for all of the standardization and unity that DICOM provides within a hospital, it is a formidable roadblock to communication outside. In particular, DICOM equipment can only communicate with other DICOM equipment DICOM equipment is expensive. And since the standard was defined by the radiologists, typically only the radiology department adheres to it. General practitioners, surgeons, clinicians and other reviewers do not generally use or possess DICOM-based equipment, and the acquisition cost for such equipment typically prohibits them from every fully participating in DICOM. Yet the sheer definition of diagnostic quality digital images is embedded in DICOM.

The various radiological modalities (e.g. X-ray, Computed Tomography (CT) scan, Magenetic Resonance (MR) scan, and the like), which deliver realtime images from the modality to display screens and networked terminals within a health care facility/infrastructure, utilize the DICOM format and protocol, to communicate the information to desired display outlets. These connected image display outlets can be purpose-built display screens and drivers, hardwired to the modality, or they can be personal computers (PCs) having appropriate hardware for interfacing with a modality, and software for handling the DICOM communication protocol and display format. Medical practitioners can view the DICOM-based image data in realtime or short-term storage (via captured display images). Images made in DICOM are very clear and well-detailed. For example, such images can commonly exhibit 4096 (12-bit), or more, grayscale levels of intensity (given the proper display screen and particular modality that supports this level), and can be used to diagnose various medical conditions to the same extent as a prepared film slide. The detail is important, as the diagnosis of many conditions, such as a collapsed lung, may require the ability to discern no more that about 20 grayscale levels on an acquired image. As a result of the detail, a typical DICOM-based image (example, a chest X-ray) may be in the range of 10-Mbytes in size. The DICOM image is typically defined as a highly scaled 12-bit pixel rather than a more-conventional 8-bit pixel. An image this size is often slow to load and manipulate on a standard computer using a standard format and display software, such as Bitmap (having the file extension—.bmp). DICOM is particularly suited to speedily process and display such large-sized images with less overhead delay.

Today, archived images are either generated on film, or digital images are printed to film so that film duplicates of images may be created for patients. This step costs facilities both in labor and in materials. Duplicating film quite often degrades image quality. Duplicate films have an increased contrast in gray level. This process of ten drops the subtle grayscale information from the duplicate films leading to inadequate information from which to make a second opinion. If the patient is seeking a second opinion from a rival medical facility, the rival facility does not have access to the digital record. In this case the specialist must order that the tests be repeated in their own medical facility. In this case the condition may not evince the same characteristics. Likewise a digital record may be needed many years later, in the event of a change in condition or possible malpractice action. In the case of court expert witnesses, failure to have access to the exact image data used by the original specialist, may cause the image evidence to be excluded. As the digital evolution proceeds, film and reprint duplication takes the image archive process one step backwards from a digital world.

Accordingly, it would be desirable to create a DICOM filly diagnostic quality image record on removable media, and give dual access to the data—one a DICOM access and the other allowing non-DICOM reviewers access to the DICOM world, as if they were viewing a realtime image directly off the given modality—without regard to elapsed time from the event or distance from the modality. The DICOM access should enable radiologists to review the information on their own viewing stations (e.g. DICOM-equipped PCs). The non-DICOM access should provide the same diagnostic quality images on any personal computer, personal digital assistant (PDA) or similar data-handling/displaying device, for review beyond the DICOM environment. In other words, even if a PC does not contain a particular type of DICOM software, the image should be viewable and capable of manipulation (e.g. capable of zoom, contrast change and other basic functions). This concept should also place the patient's diagnostic quality data in the patient's own hands. Patients would thereby gain control of their own medical records without compromising the integrity of the hospital archive or losing valuable image content. In addition, such control on the part of patients would facilitate easier transfer of records between practitioners and other interested parties as the rather stringent privacy requirements governing transmission medical records to a third party are relaxed where the information is delivered to the third party by the patient himself or herself.

Additionally, through an Internet-based network connection, patients and physicians should have the ability to tap the latest approved methods for reading, communicating and discussing the patient's case. Currently a patient must make appointments and physically go to see each physician for specialized services or second opinion. Through the Internet link provided on each CD or DVD, the patient can access these physicians, communicating the information and conferencing with the physician. The physician can use the same CD to access specialized measurement and viewing tools that may not be included in their own viewing station. The CD can also be used for physicians to conference with each other and ultimately back with the patient. Patients gain access to the finest physicians network in the world from any location in the world.

### SUMMARY OF THE INVENTION

This invention overcomes the disadvantages of the prior art by providing a system and method for recording removable media (such as data CDs) that include information enabling data to be read from a proprietary standard, such as DICOM, on any predetermined computer platform without the need of specific computer hardware or software.

A system is established within a specialist/medical facility computer to receive archived data from a variety of sources and modalities including an image scanner, a network transporting DICOM-format data from a modality (X-ray, CT scan, NMR scanner, etc.), document scanners and their various supporting text data, and form the data into appropriate files and directories using the DICOM format. In particular, the data is initially stored in archive form (typically on a removable (“portable”) media, such as a DVD or CDROM (referred to herein generally as a CD)) with a DICOM-based header that is generally universal in acceptance (such as the Part 10 standard) so that it can be recognized by a variety of native DICOM software applications, and by a universal DICOM viewing application provided with the archived DICOM data. This universal viewer, and other DICOM data can be recorded on the removable (“portable”) media along with various applications and other information that can be executed on a computer that does not include DICOM hardware and software. Where a remote PC not equipped with DICOM is used, a CD resident DICOM viewing application automatically launches. This viewing application forms a DICOM linked protocol to the images on the CD. The images are served to the CD resident viewing application just as they would be served to a live DICOM viewer over the network under DICOM protocol and in DICOM format. An exact DICOM duplicate of the original images in their original format is now available to anyone with a PC and this CD. The CD resident viewing application converts any viewer's PC into a DICOM-equipped PC for the set of images contained on the CD. The images are untouched from their original format, and are therefore fully diagnostic quality images archived for future use and conveniently accessible by all.

Inherent in this system and method is the unique concept is in creating a patient-owned and controlled removable media for storing medical records with two purposes including (1) serving primary diagnostic level information to medical specialists and practitioners and (2) communicating the same diagnostic quality information to non-specialized practitioners, clinicians, and other persons authorized by the patient in non-primary diagnostic use in a format which can be utilized in a non-DICOM world without losing the inherent primary diagnostic quality provided within the framework of DICOM.

According to an illustrative embodiment, removable media contains data that are stored for dual-purposes from a single source. The data are stored in the widely recognized standard DICOM Part 10 format to communicate with any DICOM work-station in accordance with the above-referenced DICOM 3.0 (or later) standard. The information is further capable of being used by a media resident application to create a second method of viewing, thus bringing the same DICOM diagnostic quality information into the hands of the non-DICOM general practitioners, clinicians and other reviewers.

The CD also serves as an entree to the Internet or other network-based communication system. On an Internet-enabled computer, the CD makes web-based archives, upgrades and medical services available. The CD has a link to a web site, which can be used for archiving, downloading special features or conferencing with other professionals.

According to this invention, a medical facility can create a removable media that is purchased and owned by the patient with only that particular patient's records on it. The patient can, for example, give the removable media to a specialist for a second and third opinion; to a general practitioner to post and communicate progress on the case; to a therapist so that specific treatment can be linked with underlying problems; to a cardiologist, surgeon or other higher level specialist so that a treatment plan can be conceived; and/or to a reimbursement agent so that financial plans can be made. The media provides the same images to everyone that needs to review the information in contrast to other existing systems.

### BRIEF DESCRIPTION OF THE DRAWINGS

The foregoing and other objects and advantages of the invention will become clearer with reference to the following detailed description as illustrated by the drawings in which:

FIG. 1 is a schematic diagram of an image funnel system for digitizing X-ray film, and combining it with additional data for storage on removable media according to an embodiment of this invention;

FIG. 2 is a stack layer protocol diagram of the exemplary DICOM standard as used according to an illustrative embodiment of this invention;

FIG. 3 is a schematic diagram of a system for interconnecting additional data modalities to create a removable media therefrom;

FIG. 4 is a flow diagram showing a procedure for storing DICOM data on a portable storage media;

FIG. 5 is a schematic diagram of the system combining the functions shown in FIGS. 1 and 3;

FIG. 6 is a schematic diagram of the system shown in FIG. 5 including interconnections to report and document data sources;

FIG. 7 is a schematic diagram of exemplary content for the removable media according to an embodiment of this invention;

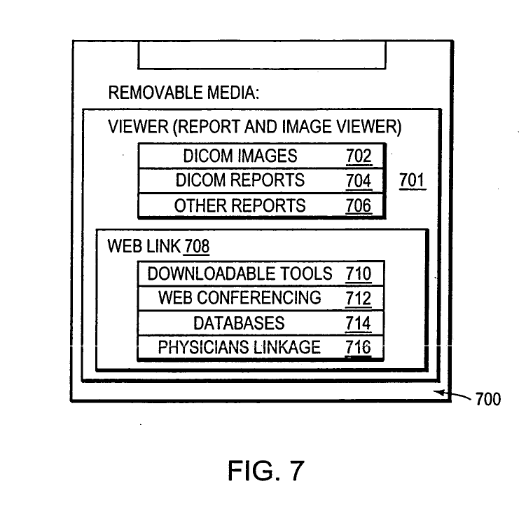

FIG. 8 is a flow diagram showing the loading and accessing of stored data either from a pre-loaded viewer or a universal DICOM viewer contained on the storage media;

FIG. 9 is a schematic diagram of exemplary distribution paths for data stored on the removable media;

FIG. 10 is a plan view of an exemplary computer display showing a work list for a universal viewer according to an illustrative embodiment; and

FIG. 11 is a plan view of an exemplary computer display showing an associated image from the worklist.

### DETAILED DESCRIPTION OF AN ILLUSTRATIVE EMBODIMENT

Systems exist today that transcribe image and report information onto compact disks (CD). The systems are available through TDK USA Corp. of Garden City, N.Y., Sorna Corporation of Eagan, Minn. (in the FilmX™ product), and Applicare Medical Imaging B.V. of the Netherlands. A primary distinction between these systems and the present invention is in the format of the stored data and in the partitioning of the data on each media. Both the TDK system and the FilmX system take the stored image out of DICOM to perform the storage phase. They offer the well-known TIFF and JPEG image formats.

Applicare's system offers storage in DICOM format. The images can only be re-read by Applicare products. Non-specialized personnel cannot extend them to general use. These systems also do not create a specific personalized single patient removable solution. Multiple patient records can be mixed on the same CD. Their intended use is in a film library that is a central and integral part of a DICOM network.

Referring now to the present invention, information used to create the patient record is obtained at the medical facility or enterprise that originated it. The facility could have various levels of equipment to feed information to the file for pressing onto the removable media.

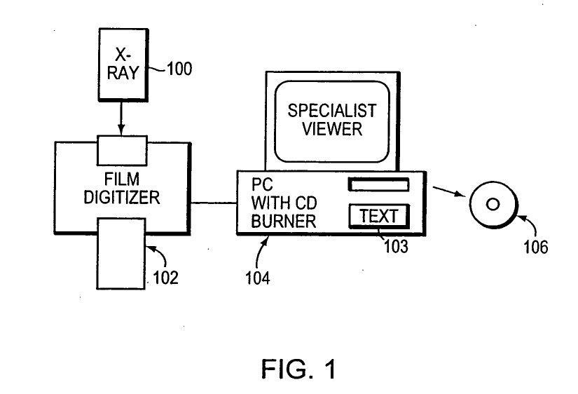

As shown in FIG. 1, X-ray films 100 or radiographs are digitized by a commercially available film digitizer 102. The patient information including name, date birth, referring physician, and a summary of the treatment plan is manually entered into the text record 103 on the facility's personal computer (PC) 104, which is joined with the images under DICOM format in the PC by the application software on the PC. The application software further lays down data (e.g. “burns) on a CD or other removable media 106 such as a disk, removable hard-drive or solid state storage media (e.g. flash memory/smart card).

The implementation of DICOM 3.0 Parts 1-15 is described in detail in the above-referenced, standards publication. The atomic unit of functionality in DICOM is the Service-Object pair (SOP) class, used to convey certain medical imaging information at the generalized data format layer. Formatting consists of a DICOM meta information section (a header) and an associated data set. Each DICOM file consists of one SOP instance. A file set contains a series of DICOM-formatted files. It is assumed that the details of file storage and formatting as described herein comport with the standards set forth in Part 10, et seq. of the DICOM standard publication, and reference is therefore made particularly thereto.

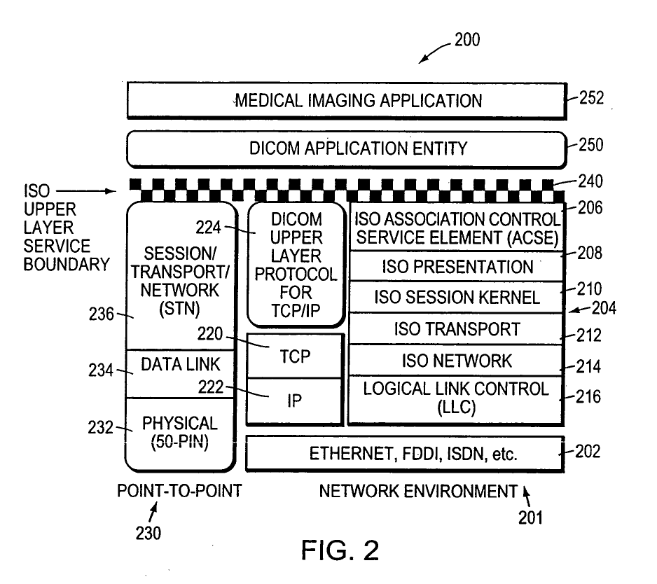

More particularly, the DICOM® 3.0 protocol and format is represented in the stack protocol layer diagram 200 of FIG. 2. At the bottom of the stack, the network environment 201 includes a networking layer (Ethernet, etc.) 202, which can be an interconnection between the modality and the host computer for manipulating and displaying DICOM imaging information. A series of communication layers 204 conforming to the International Standards Organization (ISO) are provided above the Ethernet layer 202. This grouping of layers includes the ISO Association Control Service Element (ACSE) 206, ISO Presentation 208, ISO Session Kernel 210, ISO Transport 212, ISO Network 214 and Logical Link Control (LLC) 216 layers. Also within the network environment 201 is the Transport Control Protocol (TCP) 220 and Internet Protocol (IP) 222 layers, over which resides the DICOM upper layer protocol for TCP/IP 224.

A point-to-point communication environment 230 is also provided. This supports a direct connection between an appropriately configured display device and the modality without the intervention of an Ethernet, etc. environment. This consists of a physical layer 232 (50-pin connection), a Data Link layer 234 and a Session/Transport/Network (STN) 236 layer.

An ISO Upper Layer Service Boundary 240 separates the communication layers in the network environment 201 and point-to-point environment 230 form the DICOM application entity 250 and associated medical imaging application 252. These applications allow the image to be stored in DICOM, retrieved, and manipulated.

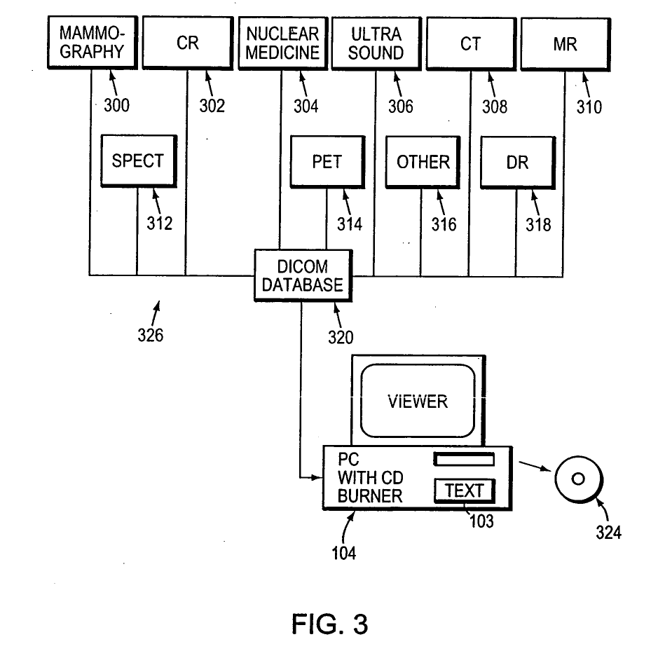

In FIG. 3, images from other modalities within radiology can be received directly from the source or retrieved from a DICOM database 320. The other image sources including mammography 300, CR 302, Nuclear Medicine 304, Ultrasound 306, CT scan (CT) 308, Magnetic Resonance Imaging 310, SPECT 312, PET 314, other image sources 316 and direct X-ray (DR) 318 are linked on a DICOM network 326 to the DICOM database 320, that is in turn linked to the digitizer (ImageFunnel) PC 104 that burns the resulting CD 324 with the information from the various diagnostic sources and databases. The format of the information stored on the CDs or other media herein can be a standard file/directory format generally recognized by a common PC operating system such as open source Linux or Windows® from Microsoft Corp. of Redmond, Wash. In essence, the media stores that data in its native format (e.g. text, DICOM, etc.).

DICOM is both a protocol and a format for medical imaging equipment. DICOM was originally intended as a standardized method for medical equipment to communicate with each other, so that a Computer Tomography (CT) image could be viewed on a medical PC other than the single viewer that is sold with the CT scanner. A DICOM image exists in being transmitted from the source (such as a CT, MR, ultra-sound) to the viewer or storage medium. As the industry began to mature a Part 10 section of the DICOM standard began to evolve. It is still evolving. When a DICOM image is stored, it is stored under a Part 10 formatting specification. Although the DICOM Part 10 specification provides an overall standard, all manufacturers of DICOM equipment do not agree on the exact format and nature of a stored image. This leads to the industry that exists at present, where a particular manufacturer or consortium of manufacturers essentially locks images within systems. The images are not truly transportable between all systems or enterprises.

As already described, the current method of transporting images between systems is to take a lower resolution or lower quality lift of the diagnostic image and bring the image into a graphic arts format such as TIFF or JPEG. When this is done the diagnostic merit of the image is lost forever.

The system and method consists of capturing the raw DICOM fully diagnostic image in the format that is transmitted and used by each manufacturer. In essence the image written on the CD is the same image as the one originated on each piece of aging equipment—just as the imaging equipment generated it originally. There is no massaging or interpreting of the image, and best of all, no reduction in image quality.

The images are fed to the computer 104 that will burn the CD through the DICOM protocol just as they would be sent to the image viewing stations. The images or collection of images are gathered and stored on the CD or removable media The software on the PC stores them in a globalized standard DICOM part 10 format, and then writes the information on the removable media. The information is stored in a database format with a keyed and dated description of the data This database can be sorted and augmented with more images.

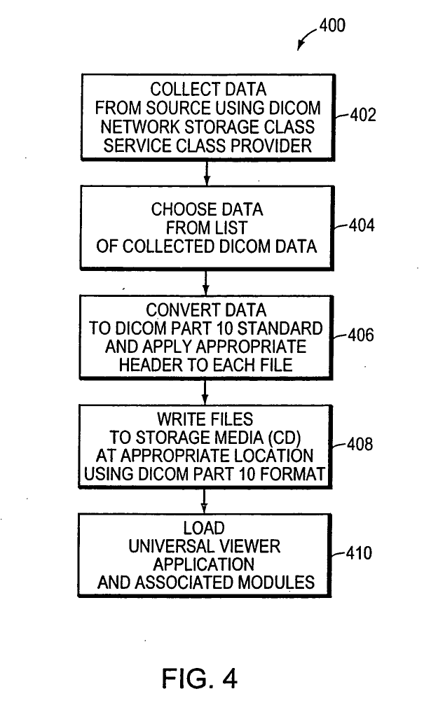

Referring now to FIG. 4, a procedure 400 for storing DICOM data on a portable (removable) media such as a CD is now described. Data is collected to form a DICOM archive (step 402) from a network, modality or storage location(s). The storage of collected data occurs in a storage class service class provider as defined by the standard. A service class provider is defined as a network-based resource providing a service requested by a host, such as a printer, archive, workstation, etc. Data in the archive of DICOM objects is then chosen by the user or by other mechanisms for storage on portable media (step 404). Any existing meta information or header is stripped from the data. Since various modalities may append modality-specific or viewer-specific information to the header, the information is reformatted so that a standard Part 10 (or other universal) header is provided (step 406). The generalized header contains slots for identifying the modality, model, type, bitcount, modality calibration information and other useful information. Some modalities can contain rather large headers. For example a nuclear medicine modality may contain approximately three hundred slots for relevant information. An X-ray modality uses a sixty-four-slot header. This information allows the creation of an “association” within a viewer, as described further below. The reformatted information is then written, in turn, to appropriate locations on a CD or other media using conventional writing (burning) applications and associated hardware adapters (step 408). In addition, a universal viewer application and associated applications (a conventional autoload/autorun application, etc, as described further below) are loaded onto the media (step 410). The loading of the viewer and other applications can occur at any appropriate point during the overall storage procedure 400.

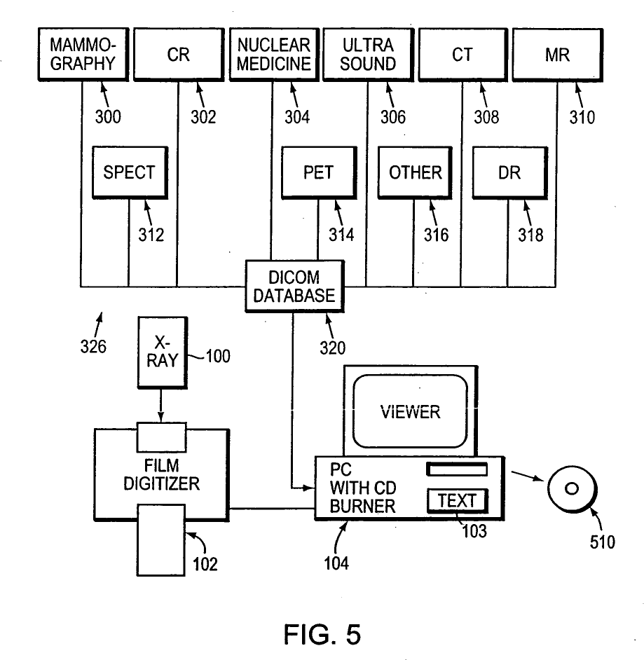

Referring briefly to FIG. 5, the acquisition computer 104 can be further linked with the film digitizer 102 so that digital images and digitized film images can be joined into the same removable record (CD 510). The storage of digitized images from a scanner can be formatted in DICOM or in another acceptable format, for review using an appropriate scanner. Note that DICOM can support JPEG and other imaging standards within its framework.

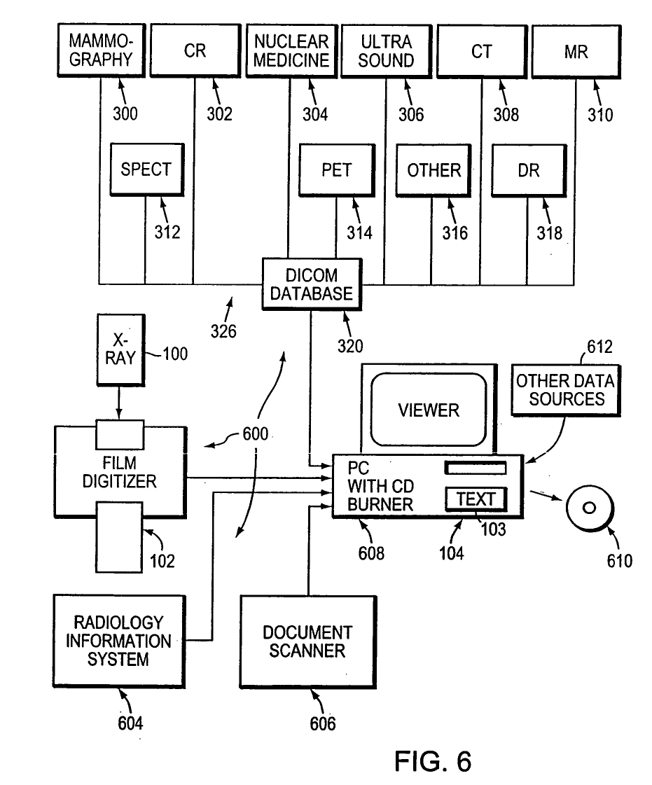

As shown in FIG. 6, the physician's report can also be retrieved or scanned and stored on a CD 610 as well. The digital sources and DICOM network 600 are shown linked to the PC 104 as well as the film digitizer 102. The Radiology Information System (RIS) 604 that is a database with a standardized format is linked to the PC 104. In cases where a RIS is not used a document scanner can acquire a digital form of the reports for inclusion on the CD 610. Note that the various connections to the computer can be accomplished using a server-based local area network, via direct bus connections to dedicated serial/parallel PC ports, via universal serial bus (USB) connections, or any other data transfer method. For example, the film digitizer can be implemented as a direct PC peripheral, often joined using a PC interface card, driver firmware and a direct bus line.

Additionally any information from other departments such as cardiac stress test procedures, test results, lab results, etc. can be either scanned, or otherwise input, onto the removable media in digital format. The scanner 606 can be employed to create appropriate files (text, word processor, bitmap-image etc.) for storage on the media Likewise data from other sources 612 can be provided to the computer in file/directory form for storage using a network or other interface.

The removable media 700 also receives a viewing application that allows any permitted person to view the CD on any PC or other data-handling device without the need for special software. The media contains a DICOM viewer application that is loadable on any predetermined computer/device 701, DICOM Images 702, DICOM Reports 704, and Other Reports from scanned sources 706. The viewer 701 also contains links to web sites 708 for downloadable tools 710, web conferencing applications 712 and links to other databases 714 or other physicians 716. Note that various universal information, not particularly relevant to the patient can be automatically burnt onto the CD when it is produced based upon instructions included on the facility's software for creating patient disks, executed on the facility computer 104.

When a patient or other interested party receives a CD containing the desired information, a viewer is first installed on the patient's computer or similar device by loading the CD. The viewer disk or viewer may contain a pass code that must be entered before information can be viewed, and that locks out the information to unauthorized parties absent the code. The code can be provided separately to the patient when the disk is delivered to him or her. It is a unique code generated by the computer during the CD creation process. The lockout code can also be based upon a preexisting code, such as the patient's social security number, patient number and the like.

Since the patient and others involved with the images may not have a DICOM viewer or DICOM viewing software on their PC, a viewer application is included with the CD. In this case, a CD resident DICOM viewing application automatically launches. This viewing application forms a DICOM linked protocol to the images on the CD. The images are served to the CD resident viewing application just as they would be served to a live DICOM viewer over the network under DICOM protocol and in DICOM format. An exact DICOM duplicate of the original images in their original format is now available to anyone with a PC and this CD. The CD resident viewing application makes anyone's PC a DICOM PC for the set of images contained on the CD. The images are untouched from their original format and are therefore fully diagnostic quality images.

This method enables a bridge between systems or enterprises without compromising image quality. Any patient can carry the CD, and any licensed practitioner with a PC can read it. Any other appointed member of the patient's support team can also use the image.

When the CD or removable media is placed in a PC that already has a DICOM compatible viewer, the software on the CD creates an active link with the medical viewing software on the PC. The link is just like an active DICOM protocol link that the viewer would receive through the network. The viewer treats the information in the same way that it receives live information on the DICOM network.

In other words, when the removable/portable media is placed in the hands of a specialist that might already have a DICOM viewer or other specialized viewer, the format of the data on the media can be read by either the media resident viewer or by the Specialized viewer on the physician's workstation. This is accomplished by a specialized system of double indexing the DICOM data so that it can be used by multiple applications. A DICOM viewer resident on a PC would effectively skip over the media resident viewer, and be able to read the DICOM data. DICOM is defined as both a file format and an active protocol. DICOM images are transmitted only through live associations. The core of the media version is to create the live association to a third party DICOM viewer as if the information were currently being transmitted to it. This is accomplished by defining the media as a DICOM database which can be queried and transmit data to the viewer. In this case transmitting data from the media reader resident on the PC to the hard drive of the same PC. The PC resident DICOM viewer responds as if it were any other DICOM database on the DICOM network. Once the media is removed from the PC, the “media resident DICOM database” is removed from the network and all PC versions of the database are expunged.

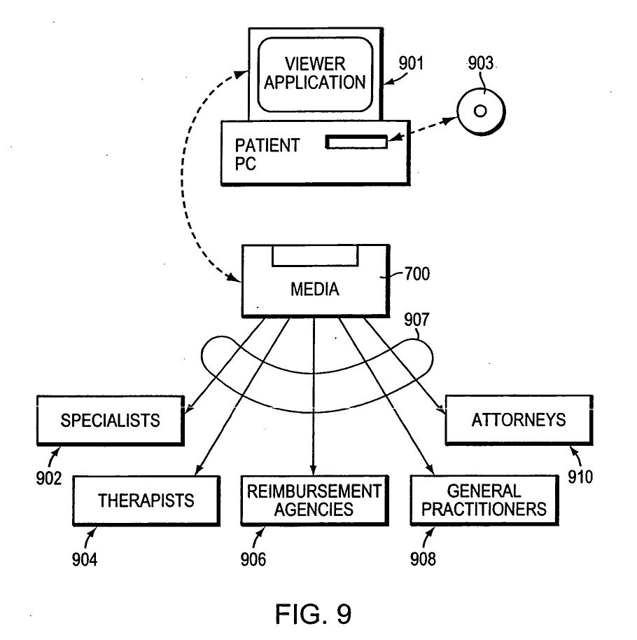

If a DICOM viewer is not present, then the media resident viewer detects this through the use of the DICOM address system and automatically opens to a database structure from which the images can be opened. Enabling viewing and reading of DICOM information on any workstation (example—patient PC 901 using CD 903 in FIG. 9). The media resident DICOM viewer is further locked so that it can only display images present on the media itself.

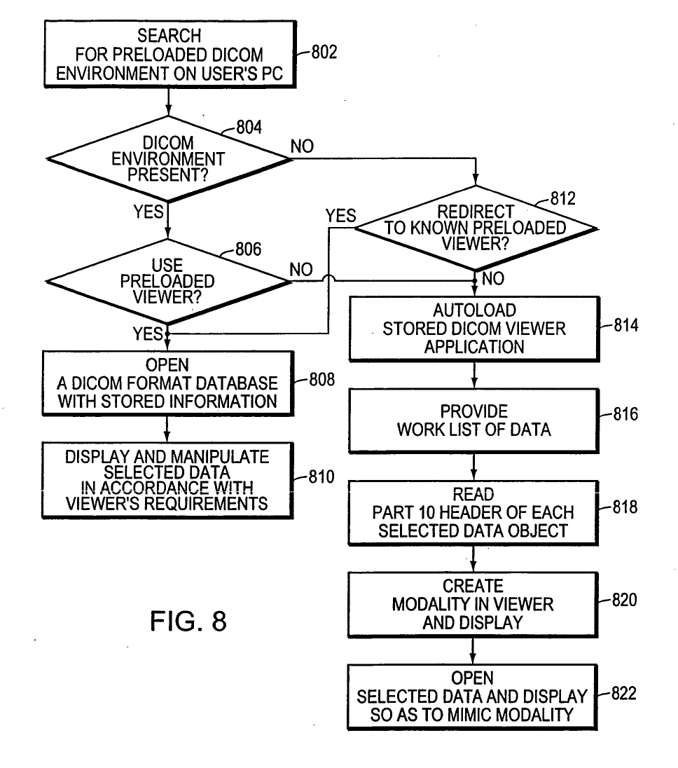

With reference now to FIG. 8, a procedure 800 for viewing/accessing stored DICOM image information is now described in further detail. The media can be equipped with a conventional application that automatically searches for a preloaded DICOM environment (step 802). This entails use of a find-file procedure that searches for a known DICOM file, attempting to locate, for example a DICOM.dir or .dic file extension on the user's PC. If a DICOM environment (viewer application) is present (decision step 804), then the procedure prompts the user as to whether he or she wishes to use the preloaded PC-based viewer (decision step 806). If so, then a DICOM format database is opened on the PC with the stored information from the media (step 808) and the user or another mechanism allows the data to be displayed in accordance with the allowable parameters of the preloaded viewer (step 810).

It is conceivable that the user may wish to use a universal viewer or one other than the preloaded viewer on his or her PC. If so, decision step 806 allows the user to branch to the opening of a universal viewer stored on the storage media (steps 814-822). For example, if the preloaded viewer is geared to a particularly modality other than that represented by the data on the storage media.

If a DICOM environment is not located on the user PC, then decision step 804 branches to decision step 812. At this point, the user is prompted as to whether he or she wishes to redirect to a particular viewer that is not located, but known to exist. The procedure branches to step 808 in which a DICOM format database is created on the users PC and the viewer can be employed, typically by manual intervention by the user to open the viewer and access a particular data file with the opened viewer (step 810).

If the universal DICOM viewer stored on the media is selected (either via decision steps 804 or 806), then the stored viewer is autoloaded onto the user's PC (step 814). A work list of the data to be associated with the viewer is provided (step 816). A live association with the data is then created across the TCP/IP backbone of the DICOM protocol. This includes the reading of selected header information (step 818) in view of the universal Part 10 standard contained in the header. The header information allows the procedure to set the particular modality (step 820). For example, if the header indicates a series of 49 CT scan images in a specific order, then that modality is set in the viewer, and this is the particular manner in which the data is displayed. Conversely if an X-ray is indicated, the modality is set to display the isolated image, as is normal for a realtime image of this type. In general, the data is displayed so as to mimic the modality.

Once the removable media has been created, the patient can distribute the media 900, through various hand and electronic channels (e.g. Internet) 907, to their own designated support team including specialists 902, therapists 904, general practitioners 908, attorneys 910, reimbursement agents 906 and others. All participants are able to review the data as if it is delivered in a realtime modality using the universal viewer or their own on a standard PC of sufficient computing power.

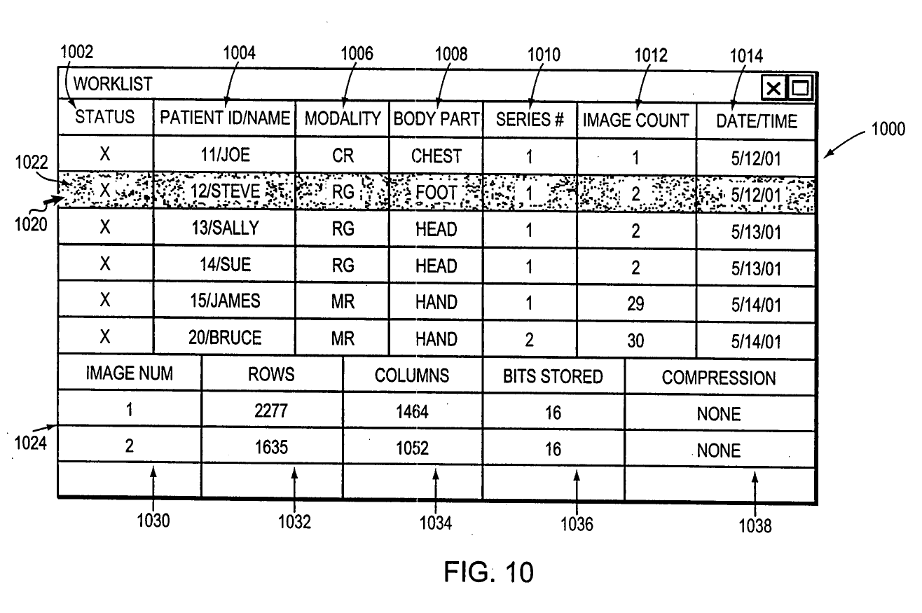

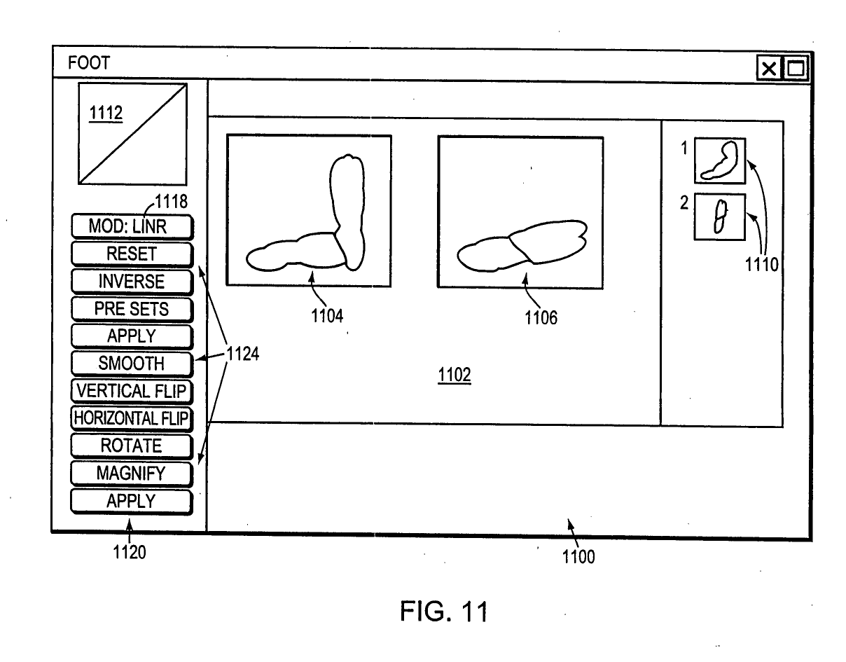

FIG. 10 shows a basic, exemplary worklist 1000 generated by the universal viewer application according to an illustrative embodiment. Each data object is listed in a respective row that can include a variety of relevant parameters in columns. For example columns can list Status (e.g. read/unread) 1002, Patient Identifier and/orName 1004, Modality (such as X-ray (RG)) 1006, subject Body Part 1008, Series Number 1010, Image Count 1012 and Date and/or Time 1014. In this example, the user has moved the cursor 1020 to Steve's row 1022, relating to two X-ray images on his foot. This data is detailed further in the lower box 1024 that details (for example) the statistics for each image including its Image Number 1030, Pixel Rows 1032, Pixel Columns 1034, Bits Stored 1036 and whether Compression is used 1038. By double-clicking (or otherwise activating the row 1022, the image can be called up onto an appropriate viewer display 1100 shown in FIG. 11.

The viewer display 1100 includes an image display screen 1102 showing the subject associated DICOM-based images 1104 and 1106 of the subject foot. These images are shown small-scale in selection boxes 1110. A contrast control window 1112 is used to select and vary image contrast. The modality is denoted by a button 1118 in a control/manipulation button box 1120. This box particularly includes a group of manipulation and control buttons that allow the user to vary a variety of parameters with respect to the displayed images. The underlying applications that are controlled by the functions can be implemented using known image-handling techniques and software. Their illustrated functions are exemplary and largely self-explanatory. Alternate buttons/functions may be provided where different modalities are mimiced by the viewer (as appropriate for that modality) or a standard set of buttons/functions can be provided for all supported modalities.

Finally, it is contemplated that an overall system according to this invention can also include the ability for an individual to maintain his or her records where they are somewhat accessible by others—for example on a disk stored in a safe place, on their home computer or PDA, or at a safe third party storage site accessible by, for example, the Internet This system can permit access by desired physicians while the individual is travelling—a disk can be carried by the person, and/or the person can carry a card, tag or bracelet that draws attention to the record's existence, and that provides necessary codes to access the information. The tag, etc can include an address for an Internet site at which the information is stored, along with appropriate passwords.

The foregoing has been a detailed description of an illustrative embodiment of the invention. Various modification and additions can be made without departing from the spirit and scope thereof. For example, while a reader/viewer for DICOM format data is described, a different format, or multiplicity of formats can be supported by the viewer of this invention. The CD or other media can also contain further data related to sound files, links to other medical databases and appropriate readers/viewers therefor, and the like. Finally, it is expressly contemplated that the principles, procedures and functions described herein can be implemented as hardware, software, including a computer-readable medium executing program instructions on a computer, or a combination of hardware and software. Accordingly, this description is meant to be taken only by way of example and not to otherwise limit the scope thereof.

What is claimed is:

1. A system for storing and retrieving medical records comprising:
means for transmitting DICOM and other data records to a computer;
means for organizing the DICOM and other data records into files and recording the files on a removable media; and
means, in the means for organizing, for supporting a reader for the DICOM data records on a remote computer stored on the removable medium.

2. The system as set forth in claim 1 wherein the means for organizing includes a means for providing a universal header to each of the data records.

3. The system as set forth in claim 2 wherein the universal header comprises a DICOM Part 10 header that includes a modality of a respective of the data records.

4. The system as set forth in claim 1 further comprising means for either selectively (a) providing the data records as a database to a preloaded DICOM-based viewer on the remote computer or (b) opening a universal viewer application that creates an association with selected of the data records.

5. The system as set forth in claim 4 wherein the means for either selectively providing or opening includes a means for recognizing a DICOM environment on the remote computer and for opening the universal viewer if no DICOM environment is recognized.

6. The system as set forth in claim 4 wherein the universal viewer application includes means for recognizing a Part 10 DICOM header in each of the selected data records, determining a modality with respect to each of the selected data records and mimicing the respective modality as each of the data records in displayed.

7. The system as set forth in claim 1 wherein the means for organizing includes means for stripping an existing DICOM-based header on each of the data records associated with a modality from which each of the data records originates, and applying a universal header to each of the data records.

8. A method for storing and retrieving medical records comprising the steps of:
transmitting DICOM and other data records to a computer;
organizing the DICOM and other data records into files and recording the files on a removable media; and
supporting a reader for the DICOM data records on a remote computer stored on the removable medium.

9. The method as set forth in claim 8 wherein the step of organizing includes a means for providing a universal header to each of the data records.

10. The method as set forth in claim 9 wherein the universal header comprises a DICOM Part 10 header that includes a modality of a respective of the data records.

11. The method as set forth in claim 8 further comprising selectively (a) providing the data records as a database to a preloaded DICOM-based viewer on the remote computer or (b) opening a universal viewer application that creates an association with selected of the data records.

12. The method as set forth in claim 11 wherein the step of either selectively providing or opening includes recognizing a DICOM environment on the remote computer and opening the universal viewer if no DICOM environment is recognized.

13. The method as set forth in claim 11 further comprising recognizing a Part 10 DICOM header in each of the selected data records, determining a modality with respect to each of the selected data records and mimicing the respective modality as each of the data records in displayed.

14. The method as set forth in claim 8 wherein the step of organizing includes stripping an existing DICOM-based header on each of the data records associated with a modality from which each of the data records originates, and applying a universal header to each of the data records.

15. A computer-readable medium executing program instructions on a computer, the program instructions performing the steps of:
accessing DICOM-based data records from a modality and providing a universal header to each of the data records, respectively;
storing each of the data records with the respective universal DICOM header on a portable storage media using a DICOM data format; and
opening the data records and viewing the data associated with the data records using a DICOM-based viewer.

16. The computer-readable medium as set forth in claim 15 wherein the step of opening includes recognizing the universal DICOM header and mimicing the modality in a display of the remote computer based upon modality information in the universal header.

17. The computer-readable medium as set forth in claim 16 wherein the step of accessing includes receiving the data records in realtime from the modality.
